(19) United States
(12) Patent Application Publication
(10) Pub. No.: US 2013/0127466 A1
(43) Pub. Date: May 23, 2013

(54) SYSTEMS AND METHODS FOR ASSESSMENT OF OXYGENATION

(71) Applicants: Periannan Kuppusamy, New Albany, OH (US); Samit Kumar Gupta, Bel Air, MD (US); Robert Lawrence Rushenberg, Omaha, NE (US)

(72) Inventors: Periannan Kuppusamy, New Albany, OH (US); Samit Kumar Gupta, Bel Air, MD (US); Robert Lawrence Rushenberg, Omaha, NE (US)

(73) Assignee: 02 Insights, Inc., Menlo Park, CA (US)

(21) Appl. No.: 13/481,545

(22) Filed: May 25, 2012

Related U.S. Application Data
(60) Provisional application No. 61/490,944, filed on May 27, 2011.

(51) Int. Cl. G01R 33/60; G01R 33/38

(52) U.S. Cl. CPC G01R 33/60; G01R 33/38
USPC 324/316; 324/319

(57) ABSTRACT

A scanner for assessing localized oxygenation of a desired region of interest includes a handheld housing having a proximal end and a distal end. A resonator coil is disposed within the housing and also disposed adjacent the distal end of the housing. The resonator coil is configured to both excite and read paramagnetic materials. A magnet is disposed within the housing and also disposed adjacent the distal end of the housing. The magnet is configured to provide a substantially uniform magnetic field over the desired region of interest. The scanner is configured to use electron paramagnetic resonance to assess localized oxygenation in the desired region.

### CROSS-REFERENCE TO RELATED APPLICATIONS

The present application claims priority from provisional patent application No. 61/490,944 (Attorney Docket No. 40279-703.101), filed on May 27, 2011, the entire contents of which are incorporated herein by reference. The present application is related to the following co-pending patent applications: US Patent Publication Nos. 2010/0172843; 2005/0203292; and U.S. Provisional Patent Application No. 61/486,519; the entire content of each is incorporated herein by reference. The present application is also related to U.S. Pat. No. 7,662,362; the entire contents of which are incorporated herein by reference.

### BACKGROUND OF THE INVENTION

The present invention generally relates to systems and methods for assessment of oxygenation. More particularly, the present invention relates to systems and methods for measuring oxygen tensions in biological systems such as wounds or organs in humans or animals, or in other regions of the body. Measurement of oxygen tension preferably utilizes paramagnetic materials and electron paramagnetic resonance (EPR) oximetry. Measurement may be conducted in any region of the body, including on the skin (cutaneous) or below the skin (subcutaneous).

Oxygen is a fundamental nutrient in the body which influences virtually every physiological process including metabolism, growth, and tissue repair. Measurement of oxygen tension has tremendous value in a number of biological settings. Thus measurement of the partial pressure of oxygen, pO₂ is useful in evaluating and understanding many physiological, pathological, and therapeutic processes. In particular, measurement of oxygen is an important parameter in providing therapy such as for treatment of wounds, as well as in diagnostic procedures.

There are a number of existing systems and methods for assessing oxygen in tissue. Some of these include the Clark electrode, fluorescence quenching, oxygen binding to myoglobin and hemoglobin, chemiluminescence, phosphoresence quenching, and spin label oximetry. However, these systems and methods may have limitations under certain circumstances, such as when used in vivo. They may lack some of the qualities needed during experimental and clinical use, such as sensitivity, accuracy, repeatability, and adequate spatial resolution.

More recently, the use of electron paramagnetic resonance (EPR) techniques have been proposed for measurement of oxygen. EPR is disclosed in greater detail in U.S. Pat. No. 5,494,030; 5,706,805; and 5,833,601; the entire contents of which are incorporated herein by reference. Electron Paramagnetic Resonance (EPR) oximetry is a technique for measuring oxygen tension. The principle of EPR oximetry is based, upon the Zeeman effect, as well as spectral broadening of absorption spectra of paramagnetic probe materials. EPR paramagnetic probe materials have unpaired electrons whose spins align with an externally applied magnetic field. Upon excitation by microwave energy, these electrons move to a higher energy state before relaxing back to the lower energy state. In the presence of oxygen molecules (which are also paramagnetic) the molecular relaxation of these paramagnetic molecules is affected in a way which causes the EPR spectrum to broaden. This broadening provides an indication of oxygen tension.

There are a number of issues today which may limit the use of EPR oximetry beyond the laboratory setting, including the impracticality of the measurement where it is required and prohibitive size of existing EPR spectrometers. For example, conventional EPR spectrometers require that the subject be placed in a large chamber so that appropriate conditions for oximetry, including the achievement of a uniform magnetic field can be achieved. On the other extreme, samples can be placed inside smaller EPR machines for analysis, but their small aperture size makes them impracticable for use on both animals and humans. In addition, many of these conventional devices are too small, or too large and are difficult to use in settings outside of the laboratory such as hospitals or clinics.

It would therefore be desirable to provide an improved EPR spectrometer for assessment of oxygenation which overcomes some of the challenges described above, thus enabling broader use of this important technology. Such systems are preferably more portable, require less storage space, and are better suited for using in a clinical setting. It would also be desirable to provide improved methods that enable the direct measurement of localized oxygen concentration in a human or animal subject. At least some of these objectives will be met by the present disclosure.

### SUMMARY OF THE INVENTION

The present invention generally relates to systems and methods for assessment of oxygenation. More particularly, the present invention relates to systems and methods for measuring oxygen tensions in biological systems such as wounds or organs in humans or animals, or in other regions of the body. Measurement of oxygen tension preferably utilizes paramagnetic materials (also referred to as paramagnetic probes) and electron paramagnetic resonance (EPR) oximetry. Measurement may be conducted in any region of the body, including on the skin (cutaneous) or below the skin (subcutaneous).

In a first aspect of the present invention, a scanner for assessing localized oxygenation of a desired region of interest comprises a handheld housing having a proximal end and a distal end. The scanner is configured to use electron paramagnetic resonance to assess localized oxygenation in the desired region of interest. A radiofrequency (RF) bridge (further explained in the detailed description) assembly having a surface resonator coil is disposed within the housing and also disposed adjacent the distal end of the. The RF bridge assembly is configured to both generate RF excitation signals and read electron paramagnetic resonance signals. The RF bridge comprises at least one of the following: an oscillator, an attenuator, a circulator, a resonator, a detector, a reference arm, a pre-amplifier, an automatic frequency controller, a SAW oscillator, or a tuning display. The following description of these elements is taken from “Theory, Instrumentation, and Applications of Electron Paramagnetic Resonance Oximetry” by Rizwan Ahmad and Periannan Kuppusamy, published Mar. 10, 2010 in Chem. Rev. 2010, 110, pages 3212-3236, the entire contents incorporated herein by reference. The EPR resonator design is important to maximize sensitivity and must be tailored to accommodate the sample with the highest possible filling factor x quality factor product. The quality factor, Q, is the ratio of energy stored to energy lost by the resonator, while the filling factor is the fraction of total RF magnetic field power entering the resonator that is incident upon the sample. A higher Q allows larger detectable changes during absorption and hence improves signal intensity. The resonator must be a mechanically stable structure and should make most efficient use of the space within the magnet. Space constraints present a major consideration in the choice of the resonator design for EPR imaging. Automatic coupling adjustment and frequency tuning can be used to suppress motion-induced distortion that occurs in biological samples. In recent years, much effort has been focused on the development of lumped-parameter RF sample cavities for L- and S-bands. Typical embodiments may utilize but are not limited to two major types of such resonators, namely, loop-gap and reentrant, have been introduced and extensively discussed in the field. Loop-gap resonators (LGRs) provide a straightforward design and high filling factors as compared to standard distributed parameter RF cavities. However, because of the open structure of the inductive loop element, LGRs have significant radiation losses unless a shield is provided. The need for the shield leads to problems in achieving an optimum magnitude of modulation field and at least a 20% increase of overall resonator dimensions The reentrant resonator (RER) design forms a closed volume, it does not require any additional shield, thus providing substantial space savings as compared to LGRs. A number of RERs constructed of ceramic silverplated material are also reported,' offering improved rigidity and stability.

In the above and other typical embodiments a magnet assembly is disposed within the housing and also disposed adjacent the distal end of the housing. The magnet assembly may comprise a combination of electromagnets and/or permanent magnets. The magnet assembly is configured to provide a substantially uniform magnetic field over the desired region of interest. The requirements for field homogeneity are more stringent for larger samples and for narrower EPR spectra line shapes. Preferably the scanner provides a magnetic field with across volume in homogeneity smaller than the smallest linewidth by at least an order of magnitude. Various embodiments of the invention may utilize, but are not limited to, Helmholtz coil designs, solenoid coil designs, or hybrid multi-coil designs for improved homogeneity of the field. In the above and other preferred embodiments the desired region of interest is coupled to a paramagnetic probe.

Additional preferred embodiments are similar to above described embodiments and may additionally provide modulation coils to modulate the substantially uniform magnetic field. As described in the above encorporated reference “Theory, Instrumentation, and Applications of Electron Paramagnetic Resonance Oximetry”: it is a common practice in CW EPR, to improve sensitivity, to modulate the magnetic field by adding an oscillating magnetic field using a pair of modulation coils and to detect the signal using a phase-locked loop detector, which is also called a phase-sensitive or a lock-in detector. The lock-in detector compares the EPR signal from the crystal with the reference signal, which comes from the same oscillator that generates the magnetic field. The lock-in detector only accepts the EPR signal that is phase coherent to the reference signal. The advantages of lock-in detection include less than 1/f noise from the detection diode and elimination of the baseline instabilities due to drift DC electronics. Additionally to improve the substantially uniform magnetic field the handheld scanner may further comprise a Hall Effect sensor for use in field generation feedback.

Additionally in a typical embodiment like the ones described above the handheld scanner may additionally comprise a processor adapted to perform parametric curve fitting of the measured electron paramagnetic resonance spectra or any order harmonic thereof. In embodiments where the substantially homogenous magnetic field is modulated signal to noise ratio may be improved by observing the peak to peak line width first harmonic spectra. This is useful for a multitude of embodiments since the majority of spin probes have parametric function line shapes such as Gaussian, Lorentzian, or Voight. This techniques is especially useful when modulating the substantially uniform magnetic field and curve fitting to the first harmonic.

In another aspect of the present invention, a method for assessing localized oxygenation of a desired region of interest comprises providing a handheld scanner, as described in the above embodiments, configured to use electron paramagnetic resonance to assess localized oxygenation in the desired region, and positioning the handheld scanner adjacent the desired region of interest, the desired region of interest having been operatively coupled to a paramagnetic probe. The method also comprises applying a substantially uniform magnetic field to paramagnetic material disposed adjacent the desired region of interest with the handheld scanner, directing energy from the handheld scanner to the desired region of interest, measuring an electron paramagnetic resonance signal from the desired region of interest, and assessing the localized oxygenation of the desired region of interest. The method may also comprise placing the region of interest into a hyperbaric environment. The method may further comprise of modulating the substantially uniform magnetic field while exciting the region of interest with the directed energy from the handheld scanner and acquiring an electromagnetic resonance spectra of the desired region. As described in the scanner embodiments above the method may also include processing the EPR spectra data including parametric curve fitting, and curve fitting of any order harmonic of the spectra. Most notably the first order harmonic is usable when modulating the substantially uniform magnetic field.

Additionally, typical embodiments of the invention as described above and their methods of use may employ tuning the handheld scanner to optimize measurements. Tunable parameters include but are not limited to: i) Radiation frequency: An increase in the radiation frequency improves the SNR but at the same time results in unwanted nonresonant absorption and reduction in penetration depth. (ii) Magnetic gradient: An increase in magnetic gradient strength thermally burdens the gradient coils and degrades SNR but improves spatial resolution. (iii) RF power: An increase in RF power improves SNR but may also result in heating of the sample and power saturation-induced line broadening. (iv) Quality factor: A high Q of a resonator, along with critical coupling, improves SNR but also leads to extra sensitivity to sample motion. (v) Modulation amplitude: An increase in modulation amplitude improves SNR but exerts extra burden on the modulation coils and also results in line shape distortion, which is generally corrected by postprocessing. (vi) Sweep time: Increasing the magnetic field sweep time for each spectral scan improves SNR but prolongs the acquisition time, which can be very critical for in vivo applications. (vii) Number of projections: For imaging, collecting data along a large number of orientations generally improves reconstruction quality but only at the cost of increased acquisition time. The above description of tuning is taken from the encorporated reference “Theory, Instrumentation, and Applications of Electron Paramagnetic Resonance Oximetry.”

In typical embodiment EPR spectra is acquired by sweeping the substantially homogeneous magnetic field under fixed frequency RF excitation. In alternate embodiments EPR signal can be measured by varying the RF excitation frequency under a constant magnitude substantially homogenous magnetic field.

Additionally preferred embodiment the paramagnetic probe comprises a lithium phthalocyanine derivative, wherein the paramagnetic probe comprises the compound of formula 4:

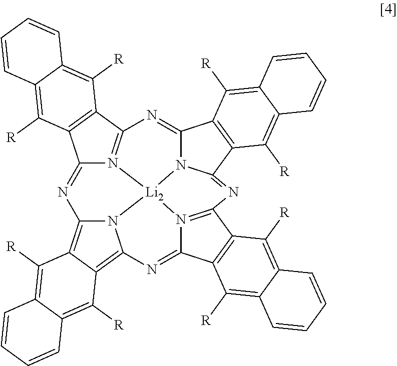

wherein R is selected from the group consisting of O(CH2)nCH3, S(CH2)nCH3, O(CH2)nCH2OH, O(CH2) [symbol] nCH2NH2, O(CH2)nCH2SH, and combinations thereof; wherein n is 1-6, or radical thereof.

In yet another preferred embodiment the paramagnetic probe comprises and wherein the particulate probe comprises the radical compound of the formula R4:

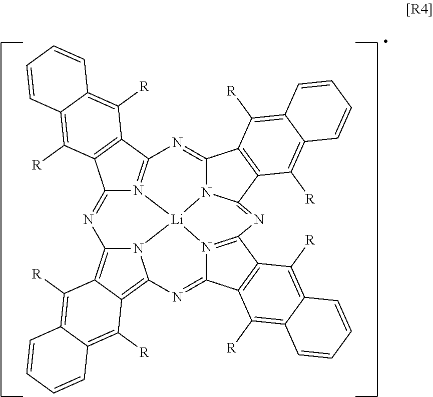

wherein R is selected from the group consisting of O(CH₂)ₙCH₃, S(CH₂)ₙCH₃, O(CH₂)ₙCH₂OH, O(CH2)ₙCH₂NH₂, O(CH₂)nCH₂SH, and combinations thereof; wherein n is 1-6, or a radical thereof.

These and other aspects and advantages of the invention are evident in the description which follows and in the accompanying drawings.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 schematically illustrates an exemplary embodiment of a handheld scanner used for oxygen assessment.

FIG. 2 schematically illustrates another exemplary embodiment of a handheld scanner used for oxygen assessment.

FIG. 3 schematically illustrates still another exemplary embodiment of a handheld scanner used for oxygen assessment.

FIG. 4 schematically illustrates a typical continuous wave EPR RF Bridge. This image is adapted from the above incorporated reference, “Theory, Instrumentation, and Applications of Electron Paramagnetic Resonance Oximetry.”

### DETAILED DESCRIPTION OF THE INVENTION

Disclosed herein are exemplary embodiments of a novel system and methods for measuring oxygen tension noninvasively or minimally invasively in either a human or animal subject. Oxygen tension measurement with the systems and methods described below are based upon the principle of electron paramagnetic resonance (EPR) oximetry. In the novel methods, any suitable paramagnetic probe for EPR oximetry such as india ink, coals, char, carbon black, lithium phthalocyanine, lithium naphthalocyanine, nitroxides, or trityl radicals is applied to a localized site on a subject and an EPR reader device consisting of a handheld scanner is used to excite and read the EPR probe material at the site of interest either under normobaric or hyperbaric pressure. The novel handheld scanner will apply a uniform magnetic field at the site of interest, excite the paramagnetic probes with a radiofrequency wave, measure the EPR signal, analyze the detected signal, and display the oxygen tension measured at the site of interest. The hardware for the magnetic field application, probe excitation, signal detection, signal analysis, and display will be contained within the handheld scanner and additional hardware which is attached to the scanner.

The handheld scanner contains magnet assembly comprising a configuration of permanent magnets and/or electromagnets which will enable creation of a uniform magnetic field over the region of interest on the subject. The electromagnets are may be ferrous cored or non-ferrous electromagnets. The handheld scanner also contains a radio frequency (RF) bridge assembly, preferably disposed adjacent to the distal end of the housing. The radio frequency bridge assembly comprises at least a surface resonator loop and optionally at least one of the following: an oscillator, an attenuator, a circulator, a detector, a reference arm, a pre-amplifier, an automatic frequency controller, a SAW oscillator, or a tuning display. The radio frequency bridge assembly is configured to excite the site of interest with radiofrequency radiation and measure resultant electron paramagnetic resonance signals from the site of interest. Three exemplary embodiments of the scanner are shown in the illustrations below.

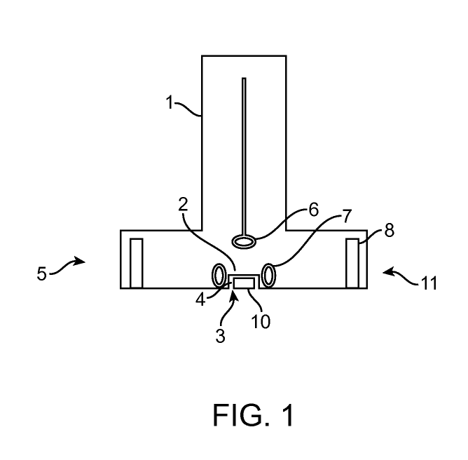

FIG. 1 illustrates an exemplary embodiment of a handheld scanner 1 that allows a uniform magnetic field 2 to be created over the region of interest 3. The uniform magnetic 2 field is created in the notched portion 4 in the distal portion 5 of the handheld scanner. In this and other embodiments described below the handheld scanner is preferably ergonomically designed to include a handle or handheld housing that is easily held by an operator, and that can be placed adjacent the region of interest. A power supply such as a battery may be disposed in the housing and the housing may be self-contained, or a tether may couple the housing with an external power supply or other components of the system such as displays, controllers, etc. The handheld scanner includes a RF bridge assembly 6, a modulation coil 7 and a magnet assembly 8, such as a permanent magnet or an electromagnet. The notched portion 4 is sized to fit over an oxygen sensing patch 10 that is placed on the skin or adjacent the area of interest. This allows the handheld scanner to be placed flat or flush against the skin 11 or other working surface. Additional details on the oxygen sensing patch are disclosed below.

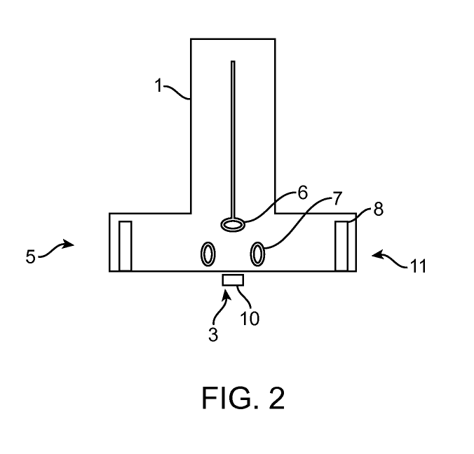

FIG. 2 illustrates another exemplary embodiment of a handheld scanner that allows a uniform magnetic field to be created over the region of interest 3. The uniform magnetic field is created in the region immediately below the scanner, adjacent the distal end 5. The scanner also includes a RF bridge assembly 6, a modulation coil 7, and a magnet assembly 8 such as a permanent magnet or an electromagnet. An oxygen sensing patch 10 (described in greater detail below) is positioned on the skin or adjacent a region of interest, and then the scanner is placed thereover to assess localized oxygenation.

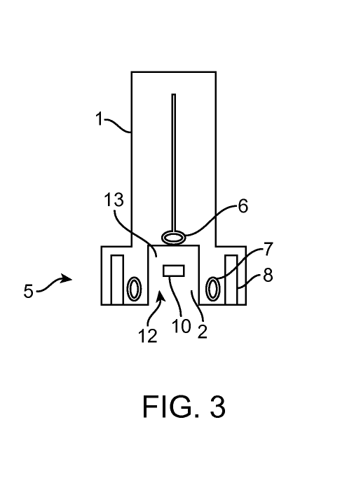

FIG. 3 illustrates still another exemplary embodiment of a handheld scanner that allows a uniform magnetic field 2 be created over the region of interest. The uniform magnetic field 2 is created in the recessed region 13 of the handheld scanner near a distal region 5 of the scanner. In this embodiment, the recessed region is sized to accept a limb or digit 12 for localized assessment of oxygenation, and also allows the scanner to sit flush against a surface. An oxygen sensing patch 10 such as those disclosed below is attached to the limb or digit to allow the assessment. Other aspects of the handheld scanner are generally similar to the previous embodiments described above. Thus, the handheld scanner also includes a RF bridge assembly 6, a modulation coil 7, and a magnet assembly 8 such as a permanent magnet or electromagnet.

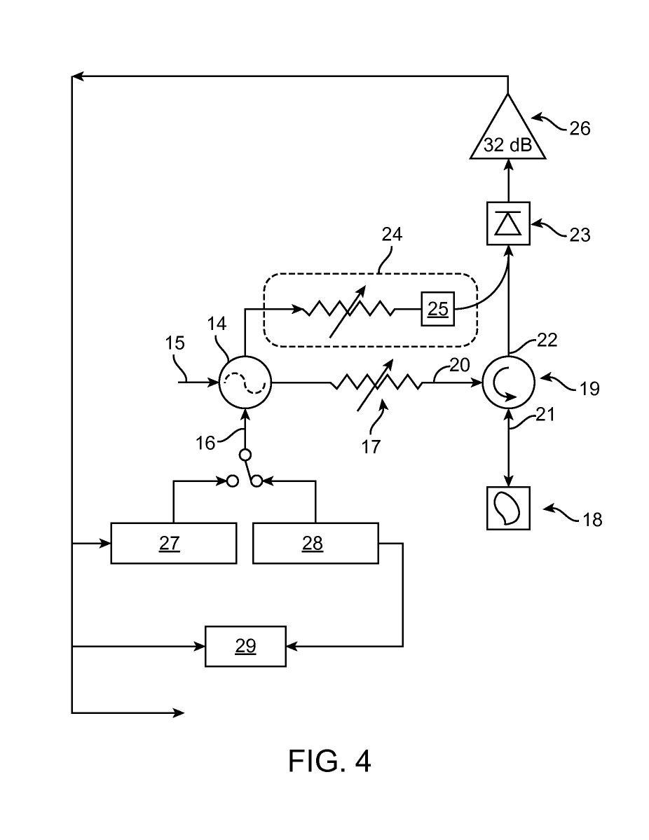

FIG. 4 shows the electronic layout of a typical RF Bridge for EPR. This figure was taken from “Theory, Instrumentation, and Applications of Electron Paramagnetic Resonance Oximetry” by Rizwan Ahmad and Periannan Kuppusamy, published Mar. 10, 2010 in Chem. Rev. 2010, 110, pages 3212-3236. Oscillator 12 is used to generate RF energy. The frequency of RF energy is generally varied with mechanical 13 and electrical means 14. While mechanical adjustments are used for coarse tuning, electronic adjustments are applied for fine tuning. The oscillator must have a stable output frequency and amplitude, as even slight changes can introduce distortion in the data. Attenuator 15 precisely controls the amount of RF energy delivered to the resonator 16. It must be very stable over time and a broad temperature range. The circulator 17 allows reflected energy from the resonator at port 19 to reach the detector diode at port 20 while blocking high-level excitation energy from port 18 to reach port 20. The resonator 16 is used to amplify small changes induced in the RF radiation due to the magnetic resonance of the desired region of interest. The change in RF energy absorbed by the desired region of interest, upon magnetic resonance, changes the impedance of the resonator. This change in impedance changes the reflection coefficient of the resonator, resulting in reflected RF power fluctuation. In CW EPR, it is this fluctuation of the reflected RF power that is converted into an EPR signal. The detector 21 converts RF energy reflected from the resonator 16 into a baseband signal. It is generally comprised of a diode detector and a passive low pass filter. The electrical output signal from a typical detector diode is 1500 mV output per mW of RF input. Because excessive RF power can permanently damage the diode, additional protection circuitry is included to monitor and limit the diode current. The reference arm 22 is used to apply small RF power to bias the detector diode into the more sensitive operating region. An RF phase 23 shifter synchro-nizes reference arm power with the reflected power from the resonator 16. Many home-built units do not have a reference arm and require off-resonance coupling of the resonator for the bias. The preamplifirer 24 amplifies the small signal (typically less than 10 mV) from the detector for further filtering and amplification by lock-in detector (signal channel). The automatic frequency controller (AFC) 25 modulates the frequency of the RF source with a 70 kHz signal. It further processes the 70 kHz component of the signal coming from the preamplifier 24 to provide feedback to electronically match the RF oscillator frequency to that of the resonator. The SAW oscillator 26 generates a sawtooth waveform (in the range of 400 Hz) to provide a frequency sweep for the tuning mode. The tuning display 27 displays an oscillator frequency sweep (x-axis) versus reflected power from the resonator (y-axis) during the tuning mode. It allows visual feedback for tuning the oscillator frequency to the resonator frequency.

In use, paramagnetic material preferably disposed in an adhesive patch is applied to the region of interest such as a wound or other tissue. The handheld scanner is advanced toward the region of interest and activated. A uniform magnetic field from the handheld scanner is directed to the paramagnetic material and energy is also applied thereto. EPR methods are then used to assess oxygenation of the localized region of interest. In a preferred embodiment, this method is used to assess oxygenation adjacent wounds. It may also be used to assess oxygenation of other tissues such as those that are below the skin.

The additional hardware components required for signal processing may be integrated into the handheld scanner, or they may be integrated into an attachment coupled to the handheld scanner. Additional information about EPR is disclosed in Appendix A which contains the journal article “Theory, Instrumentation, and Applications of Electron Paramagnetic Resonance Oximetry” by Rizwan Ahmad and Periannan Kuppusamy, published Mar. 10, 2010 in Chem. Rev. 2010, 110, pages 3212-3236, the entire contents incorporated herein by reference.

In order to enable use in a hyperbaric or pressurized environment, either the entire system may be placed and used in a hyperbaric environment, or the handheld scanner alone can be placed in the hyperbaric environment for use, and attached to any necessary additional hardware components which are outside of the hyperbaric environment.

Additionally, chemical probe formulations for detecting oxygen and implantation of oxygen sensing probes is disclosed in greater detail in US Patent Publication No. 2005/0203292 and 2010/0172843, the entire contents of which are incorporated herein by reference. U.S. Pat. No. 7,662,362 also discloses further details on oxygen sensing probes, the entire contents of which are incorporated herein by reference. Encapsulation of an oxygen sensing probe into a polymer such as a patch is disclosed in greater detail in U.S. Provisional Patent Application No. 61/486,519, the entire contents of which are incorporated herein by reference.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

What is claimed is:

1. A scanner for assessing localized oxygenation of a desired region of interest, said scanner comprising:
a handheld housing having a proximal end and a distal end;
a radio frequency bridge assembly disposed within the housing and disposed adjacent the distal end of the housing, the radio frequency bridge assembly configured to both generate electromagnetic signals and measure electron paramagnetic resonance signals; and
a magnet assembly disposed within the housing and disposed adjacent the distal end of the housing, the magnet assembly configured to provide a substantially uniform magnetic field over the desired region of interest,
wherein the scanner is configured to use continuous wave electron paramagnetic resonance to assess localized oxygenation in the desired region.

2. A system for assessing localized oxygenation of a desired region of interest comprising the scanner of claim 1, wherein the desired region is operatively coupled to a paramagnetic probe.

3. The scanner of claim 1, where in the radio frequency bridge comprises at least one of the following: an oscillator, an attenuator, a circulator, a resonator, a detector, a reference arm, a pre-amplifier, an automatic frequency controller, a SAW oscillator, or a tuning display.

4. The scanner of claim 1, further comprising at least one modulation coil for modulation of the substantially uniform magnetic field.

5. The scanner of claim 1, wherein the magnet assembly comprises one or more of the following: non-ferrous electromagnets, ferrous core electromagnets, or permanent magnets.

6. The scanner of claim 3, wherein a non-ferrous electromagnet comprises a Helmholtz coil, a solenoid, or a hybrid multi-coil design for improved homogeneity of the substantially homogenous field.

7. The scanner of claim 1, further comprising a Hall Effect sensor.

8. The scanner of claim 1, wherein the scanner is entirely and portably self-contained within the handheld housing.

9. The scanner of claim 1, further comprising a processor adapted to perform parametric curve fitting to a measurement of the electron paramagnetic signal or any order harmonic thereof.

10. The scanner of claim 2, wherein the paramagnetic probe comprises the radical compound of the formula R4: 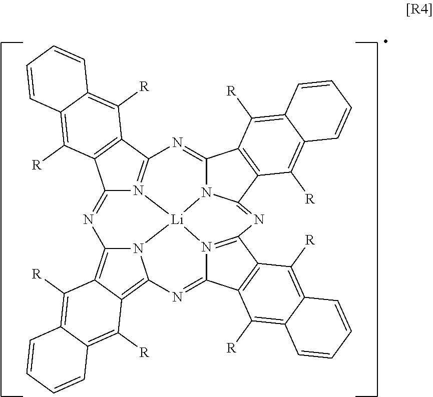
wherein R is selected from the group consisting of O(CH₂)ₙCH₃, S(CH₂)ₙCH₃, O(CH₂)ₙCH₂OH, O(CH₂)ₙCH₂NH₂, O(CH₂)nCH₂SH, and combinations thereof; wherein n is 1-6, or a radical thereof.

11. The scanner of claim 2, wherein the paramagnetic probe comprises the compound of formula 4: 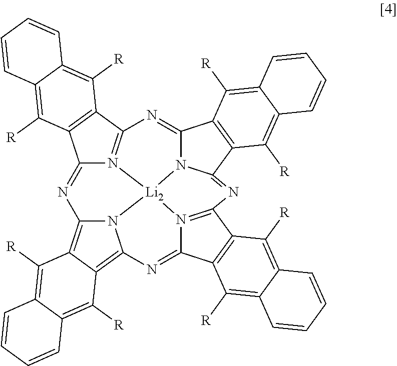
wherein R is selected from the group consisting of O(CH2)nCH3, S(CH2)nCH3, O(CH2)nCH2OH, O(CH2) [symbol] nCH2NH2, O(CH2)nCH2SH, and combinations thereof; wherein n is 1-6, or radical thereof.

12. A method for assessing localized oxygenation of a desired region of interest, said method comprising:
providing a handheld scanner configured to use electron paramagnetic resonance to assess localized oxygenation in the desired region;
positioning the handheld scanner adjacent the desired region of interest;
operatively coupling a paramagnetic probe to the desired region of interest;
applying a substantially uniform magnetic field to desired region of interest with the handheld scanner;
directing energy from the handheld scanner to the region of interest; measuring an electron paramagnetic resonance signal from the desired region of interest and
assessing the localized oxygenation of the desired region of interest.

13. The method according to claim 12, further comprising placing the region of interest into a hyperbaric environment.

14. The method of claim 12, further comprising processing an electromagnetic resonance spectra data set with parametric curve fitting.

15. The method of claim 12, further comprising modulating the substantially uniform magnetic field

16. The method of claim 12, further comprising sweeping the magnitude of the substantially uniform magnetic field while exciting the desired region of interest with the directed energy from the handheld scanner and;
wherein measuring the electron paramagnetic resonance signal comprises acquiring an electromagnetic resonance spectra of the desired region of interest.

17. The method of claim 12, further comprises tuning the handheld scanner.

18. The method of claim 12, wherein the electron paramagnetic resonance signal is acquired by varying the energy from the handheld scanner with the substantially uniform magnetic field remaining fixed in magnitude.
